(19) United States
(12) Patent Application Publication
(10) Pub. No.: US 2008/0110752 A1
(43) Pub. Date: May 15, 2008

(54) SYSTEM AND METHOD FOR HIGH-ENERGY SPUTTERING USING RETURN CONDUCTORS

(76) Inventors: Michael W. Stowell, Loveland, CO (US); Manfred Ruske, Kerpen (DE)

Correspondence Address: COOLEY GODWARD KRONISH LLP;ATTN: Patent Group, Suite 1100, 777 - 6th Street, NW, WASHINGTON, DC, 20001, US

(21) Appl. No.: 11/558,230

(22) Filed: Nov. 9, 2006

(51) Int. Cl. C23C 14/00

(52) U.S. Cl. 204/298.08; 204/298.02

(57) ABSTRACT

A system and method for sputtering is described. One embodiment includes a sputtering system that includes a vacuum chamber; a gas box secured to the inner surface of the vacuum chamber; a plurality of return conductors engaged with the gas box, the plurality of return conductors extending through the vacuum chamber; and a plurality of seals configured to engage corresponding ones of the plurality of return conductors, the plurality of seal configured to maintain the vacuum inside the vacuum chamber.

### COPYRIGHT

A portion of the disclosure of this patent document contains material that is subject to copyright protection. The copyright owner has no objection to the facsimile reproduction by anyone of the patent disclosure, as it appears in the Patent and Trademark Office patent files or records, but otherwise reserves all copyright rights whatsoever.

### FIELD OF THE INVENTION

The present invention relates to sputtering systems and methods. In particular, but not by way of limitation, the present invention relates to systems and methods for high-energy sputtering using highly-conductive return conductors.

### BACKGROUND OF THE INVENTION

Sputtering is used in several industries to deposit and adhere material to substrates. For example, sputtering is used extensively in semiconductor, glass, and display manufacturing. Sputtering is well-known in the art and is only described briefly herein. Those of skill in the art are very familiar with this process.

In basic sputtering, a target material is placed inside a process chamber. This target material is often referred to as the “cathode,” and the two terms are used interchangeable in this document. A power supply applies a negative potential to the target, which causes the target to emit electrons. These electrons move toward a return path—called an “anode.” The anode typically includes any grounded surface, including the inner walls of the process chamber.

As the electrons move from the target toward the anode, they pass through an inert gas introduced into the process chamber. The electrons energize the inert gas, thereby forming a plasma. Ions from the plasma are attracted to the negatively charged target and when they impact the target, small particles of the target are ejected (sputtered). Most of these sputtered particles are deposited on and adhere to a nearby substrate. Some of the particles also adhere to the anode surfaces.

To complete the electrical circuit, the electrons must move from the target through the gas to the anode and back to the power supply. This return path includes two portions: inside the chamber and outside the chamber. The path inside the chamber typically includes the electrons returning along the anode surfaces internal to the process chamber, then along the process chamber walls, and then back through the shortest path of resistance. This shortest path of resistance is typically the path around the insulator of the cathode and/or the dark space shielding. The path outside the chamber typically includes the outer walls of the chamber (or a cathode box attached to the outer walls of the chamber) and a connection to the power supply.

For the purposes of this document, the term “power supply” is used broadly. It encompasses stand-alone power supplies, power supplies integrated with impedance matching networks, power supplies operated in conjunction with impedance matching networks, AC, DC, pulsed DC, RF power supplies, switching power supplies, etc.

These typical return paths inside the process chamber are problematic for high-power/high-frequency power supplies because the return paths are too resistant to electron flow. First, skin effects force the electrons to flow along the surface of the inside of the process chamber, thereby reducing the effectiveness of the return path. And as the frequency of the power supply increases, this skin effect becomes more pronounced and reduces the effectiveness of the return path to unacceptable levels. Moreover, the resistance of the inner portions of the process chamber are further increased by the manufacturing process for the process chamber. These chambers are generally stainless steel and are roughed by the use of a bead blast. Rough surfaces present far more resistance to electron flow than do smooth surfaces, and stainless steel is a poor conductor.

The primary problem with high resistance is that it causes a voltage differential to develop at certain points in the process chamber. This voltage differential can cause arcing and localized plasma formation. These localized plasmas cause sputtering of internal components of the process chamber and even the process chamber itself. These unwanted sputtered particles are deposited as impurities on the substrate. Further, the unwanted sputtering can become so extreme that it destroys the process chamber.

One solution to the resistance problem is to form the process chamber out of a highly-conductive material such as gold or silver. But given the large size of most commercially-used sputtering systems, it is impractical to use these expensive materials on a large scale.

Present sputtering technology does not work adequately with all power supplies and in particular not with high-energy/high-frequency power supplies. Accordingly, a system and method are needed to address the shortfalls of present technology and to provide other new and innovative features.

### SUMMARY OF THE INVENTION

Exemplary embodiments of the present invention that are shown in the drawings are summarized below. These and other embodiments are more fully described in the Detailed Description section. It is to be understood, however, that there is no intention to limit the invention to the forms described in this Summary of the Invention or in the Detailed Description. One skilled in the art can recognize that there are numerous modifications, equivalents and alternative constructions that fall within the spirit and scope of the invention as expressed in the claims.

The present invention can provide a system and method for sputtering. In one exemplary embodiment, the present invention can include a vacuum chamber; a gas box secured to the inner surface of the vacuum chamber; a plurality of return conductors engaged with the gas box, the plurality of return conductors extending through the vacuum chamber; and a plurality of seals configured to engage corresponding ones of the plurality of return conductors, the plurality of seal configured to maintain the vacuum inside the vacuum chamber.

### BRIEF DESCRIPTION OF THE DRAWINGS

Various objects and advantages and a more complete understanding of the present invention are apparent and more readily appreciated by reference to the following Detailed Description and to the appended claims when taken in conjunction with the accompanying Drawings wherein:

FIG. 1 shows a cross section of a typical sputtering system;

FIG. 2 shows a cross section of a typical sputtering system during operation;

FIG. 3 is an illustration of a gas box attached to the inner wall of a process chamber;

FIG. 4 is an illustration of the underside of a gas box;

FIG. 5 is an illustration of the underside of a gas box constructed in accordance with one embodiment of the present invention;

FIG. 6 shows a cross section of a sputtering system constructed in accordance with one embodiment of the present invention;

FIG. 7 illustrates the outside wall of a process chamber constructed in accordance with the principles of one embodiment of the present invention; and

FIG. 8 illustrates the inside wall of a process chamber constructed in accordance with the principles of the present invention.

### DETAILED DESCRIPTION

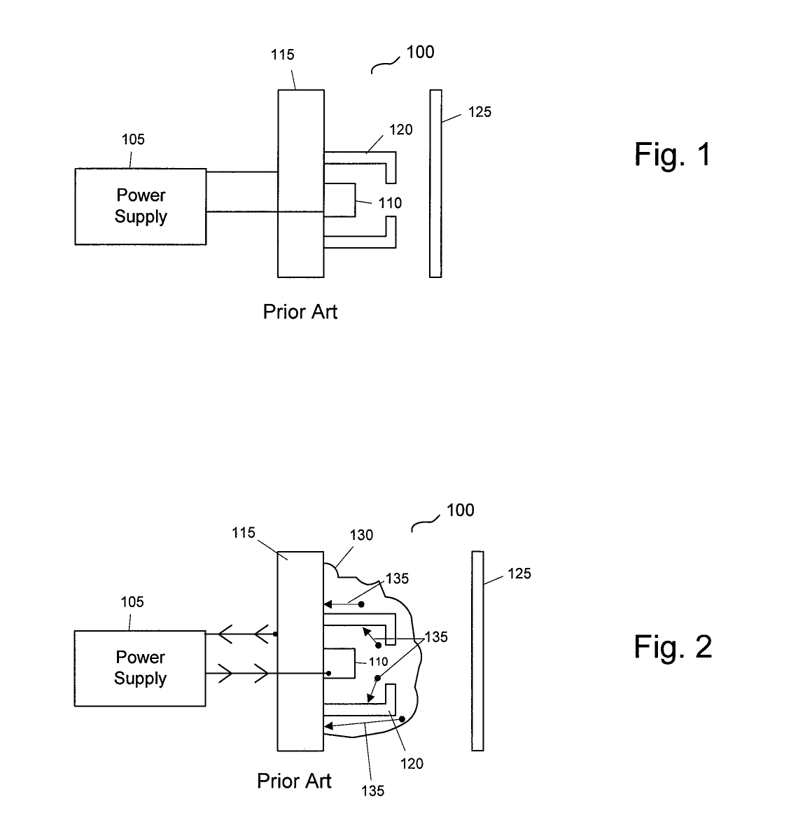

Referring now to the drawings, where like or similar elements are designated with identical reference numerals throughout the several views, and referring in particular to FIGS. 1 and 2, the illustrate a typical sputter system 100. This system includes a power supply 105. The power supply could be typically a DC, AC, pulsed DC, RF or other power supply. As previously discussed, the power supply 105 could be attached to an impedance matching network, include an integrated impedance matching network, or operate in conjunction with any type of tuning network. For clarity, “impedance matching network” as used in this document includes typical impedance matching networks and any other tuning network.

The power supply 105 is connected to the target 110, which is located inside the process chamber 115. During operation, an inert gas is release around the target 110, preferably through the use of a gas box 120 that helps distribute the gas evenly. The gas box 120 typically partially encloses the target 110. The portion of the gas box 120 between the target 110 and the substrate 125 is open so that sputtered particles can be deposited on the substrate.

When power is applied to the target 110, electrons escape and excite the surrounding gas, thereby forming the plasma 130. These electrons seek a return path 135, which as previously described, generally involves the inner portions of the process chamber 115.

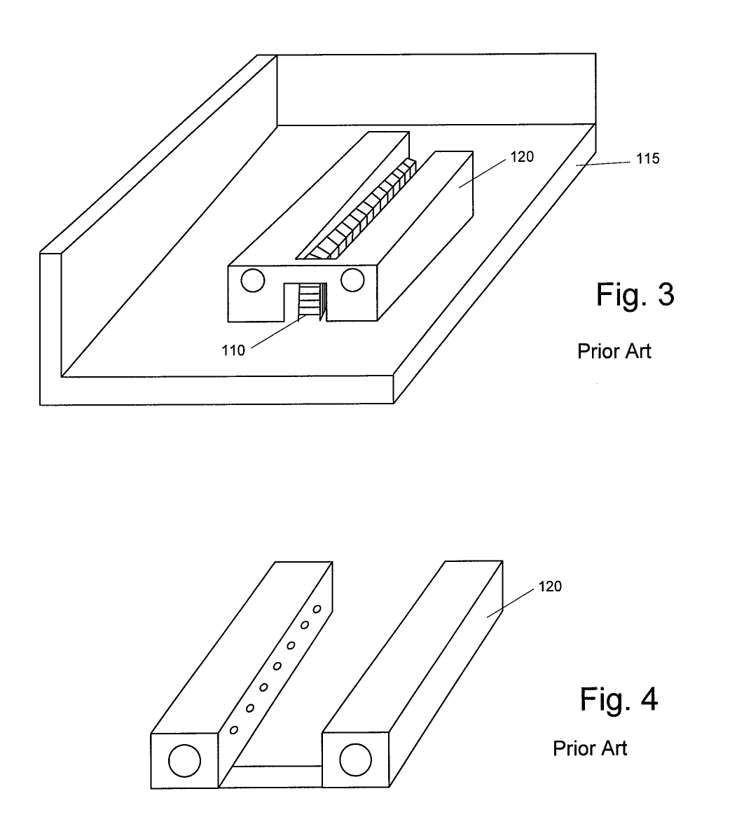

FIG. 3 illustrates the inside of a process chamber 115, including the target 110 and the gas box 120.

FIG. 4 illustrates the underside of a typical gas box 120. With relation to FIG. 3, the underside is the portion contacting the inner wall of the process chamber 115.

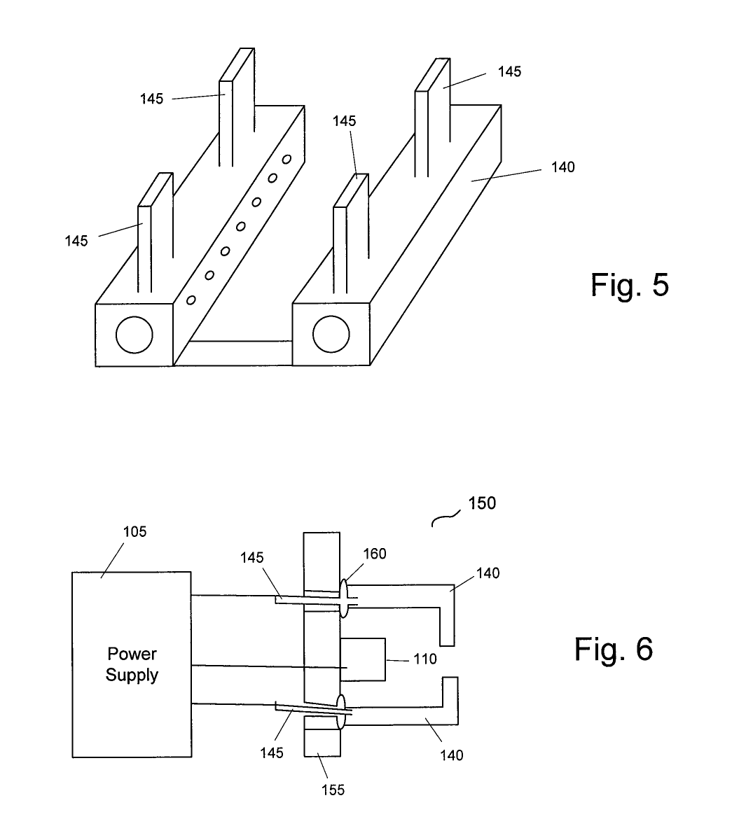

FIG. 5 illustrates the underside of a gas box 140 constructed in accordance with the principles of one embodiment of the present invention. This gas box includes four protruding return conductors 145. These return conductors 145 are configured to mate with corresponding female receivers or holes in the process chamber. O-rings (not shown) located around the return conductors 145 or other seals are used to preserve the vacuum inside the process chamber. Moreover, the return conductors 145 can include fasteners (not shown) for tightening the return conductor to the O-rings and securing the gas box to the process chamber

The return conductors 145 are typically formed of highly conductive materials such as copper. They can be mechanically attached to a flat-bottomed gas box or they can be integrally formed with the gas box. Moreover, the number, shape, and location of the return conductors can be varied. For example, the return conductor could be rectangular, square, cylindrical, etc. And in one embodiment, two or more return conductors are connected to a plate. This plate can then be attached to the gas box.

FIG. 6 is a cross section of a sputtering system 150 constructed in accordance with one embodiment of the present invention. This embodiment includes a gas box 140 with return conductors 145. These return conductors 145 pass through the process chamber wall 155 and are connected back to the power supply 105 through high-quality conductors such as copper straps. An O-ring 160 sits between the gas box 140 and the hole passing through the process chamber 155.

During operation, electrons from the target 110 pass through the inert gas and return to the power supply 105 using the return conductors 145. By increasing the amount of surface area in the return path, the return conductors 145 significantly reduce the resistance, thereby preventing arcing and unintended sputtering. These return conductors 145 provide such an improvement in the return path that full scale commercial sputtering systems can be developed and operated with RF power sources.

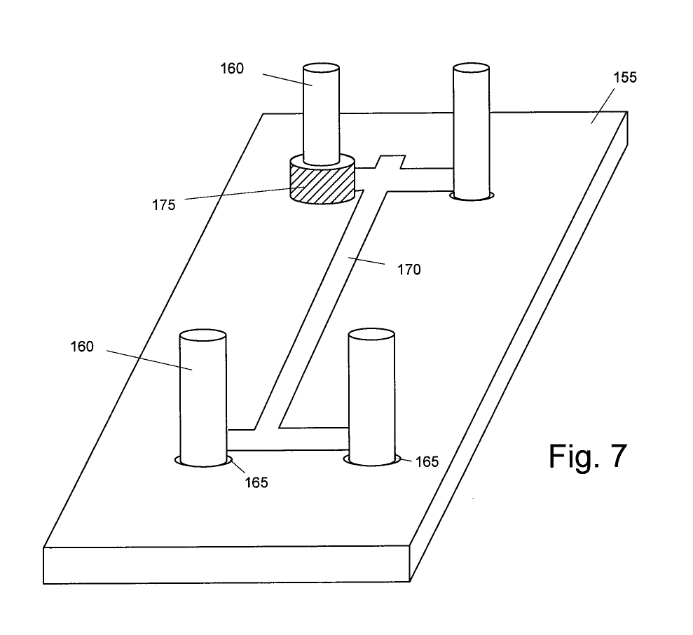

FIG. 7 illustrates the outer surface of a process chamber 155. This portion of the process chamber 155 includes four receivers 165 that permit the return conductors 160 to pass from the inside of the chamber to the outside of the chamber. More or less receivers could be used, and more or less return conductors could be used. The exact number of receivers and return conductors can be based on the power and frequency of the power supply used to drive the sputtering system. Notably, the receivers can be lined with a highly conductive material such as copper.

This embodiment also includes conductive strips 170 placed on the outside of the process chamber. Typically, the process chamber is manufactured from stainless steel, which is a poor conductor. The conductive strips can be formed of highly conductive material such as copper and provide a mechanism for moving electrons from the return conductors 160 to the power supply. Alternatively (or in addition), the return conductors can be connected directly to the power supply by highly-conductive strips or wires.

This embodiment also includes a fastener 175 for mechanically attaching the return conductor 160 to the process chamber 155. For illustration purposes, only one fastener 175 is illustrated. But those of skill in the art understand that more fasteners can be used. Fasteners are known in the art and not discussed in detail herein.

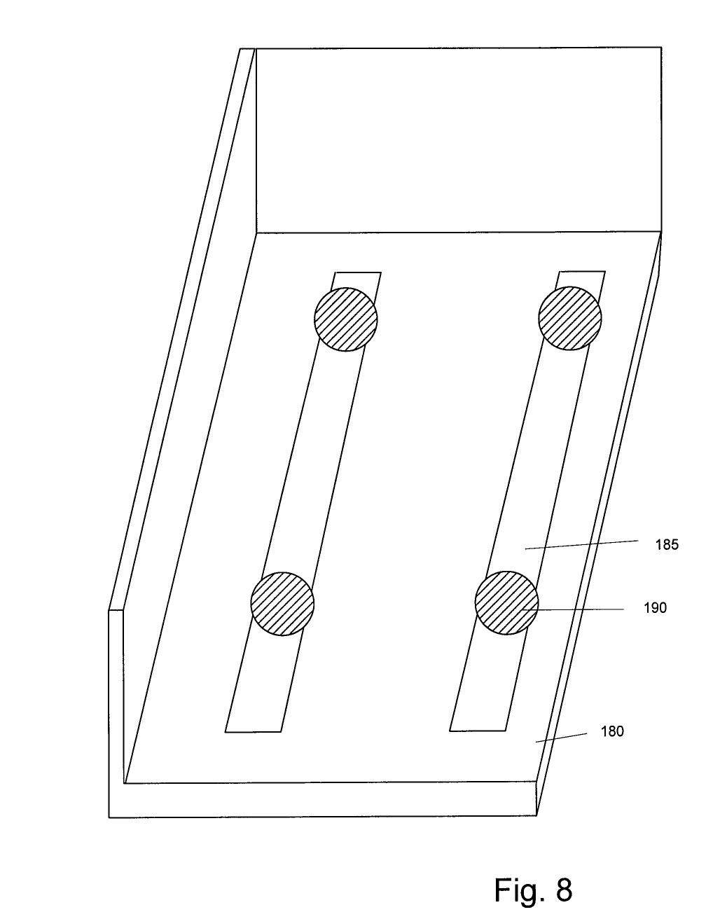

Referring now to FIG. 8, it illustrates the inside of a process chamber 180 in accordance with another embodiment of the present invention. In this embodiment, highly-conductive strips 185 are placed on the inner surface of the process chamber 180. These highly-conductive strips engage the head portion 190 of a return conductor. The gas box can be placed on top of these strips 185 in certain embodiments.

In conclusion, the present invention provides, among other things, a system and method for improved operation of sputtering devices. Those skilled in the art can readily recognize that numerous variations and substitutions may be made in the invention, its use and its configuration to achieve substantially the same results as achieved by the embodiments described herein. Accordingly, there is no intention to limit the invention to the disclosed exemplary forms. Many variations, modifications and alternative constructions fall within the scope and spirit of the disclosed invention as expressed in the claims.

What is claimed is:

1. A sputtering system comprising:
vacuum chamber having an inner surface and an outer surface;
a gas box secured to the inner surface of the vacuum chamber;
a plurality of return conductors engaged with the gas box, the plurality of return conductors extending through the vacuum chamber; and
at least one seal configured to engage the plurality of return conductors and the vacuum chamber, the plurality of seal configured to maintain the vacuum inside the vacuum chamber;
whereby the plurality of return conductors provide a return path for electrons to travel from the inner surface of the vacuum chamber to the outer surface of the vacuum chamber.

2. The sputtering system of claim 1, further comprising:
a power supply configured to provide power to a target located inside the vacuum chamber.

3. The sputtering system of claim 2, wherein the power supply comprises an RF power supply.

4. The sputtering system of claim 2, wherein the power supply comprises an impedance matching network.

5. The sputtering system of claim 1, wherein at least one of the plurality of return conductors is connected to the power supply.

6. The sputtering system of claim 1, wherein the plurality of return conductors comprise copper.

7. The sputtering system of claim 1, wherein the plurality of return conductors are integrated with the gas box.

8. The sputtering system of claim 7, wherein the gas box comprises copper.

9. A sputtering system comprising:
vacuum chamber having an inner surface and an outer surface;
a gas box secured to the inner surface of the vacuum chamber;
a return conductor engaged with the gas box, the return conductor extending from the inner surface of the vacuum chamber to the outer surface of the vacuum chamber;
a seal configured to engage the inner surface of the vacuum chamber and the return conductor; and
an electrical connector connected to the return conductor, the electrical connector configured to provide a return path for electrons to travel from the return conductor to a power supply.

10. A sputtering system component comprising:
a gas box for distributing gas around a target, the gas box configured to be secured to a sputtering process chamber; and
a return conductor coupled with the gas box, the return conductor extending from the gas box through the sputtering process chamber, thereby providing a return path for electrons to travel from the inside of the sputtering process chamber to the outside of the sputtering process chamber.

11. The sputtering system component of claim 10, wherein the return conductor and the gas box are integrated.

12. The sputtering system component of claim 11, wherein the return conductor comprises copper.

13. The sputtering system component of claim 12, wherein the gas box comprises copper.
